(19) United States
(12) Patent Application Publication
(10) Pub. No.: US 2019/0207342 A1
(43) Pub. Date: Jul. 4, 2019

(54) DEVICES WITH ORTHOGONAL CONNECTORS

(71) Applicant: Arista Networks, Inc., Santa Clara, CA (US)

(72) Inventors: Charles Melvin Aden, Santa Clara, CA (US); Robert Wilcox, Saratoga, CA (US)

(21) Appl. No.: 16/234,459

(22) Filed: Dec. 27, 2018

Related U.S. Application Data
(60) Provisional application No. 62/611,951, filed on Dec. 29, 2017.

(51) Int. Cl. H01R 13/514; H01R 12/72; H01R 12/73; H01R 12/79; H01R 43/26; H05K 3/36; H05K 1/14

(52) U.S. Cl. CPC H01R 13/514; H01R 12/724; H01R 12/73; H01R 12/79; H05K 2201/1031; H05K 3/368; H05K 1/144; H05K 2201/042; H05K 2201/10333; H01R 43/26

(57) ABSTRACT

Apparatus with orthogonal connectors. The apparatus includes a circuit board and the circuit board includes a set of processing devices. A first connector is coupled to the circuit board and the set of processing devices. A first housing of the first connector is configured to interface with a second housing of a second connector while the first connector and second connector are inserted into a third connector

### CROSS-REFERENCE TO RELATED APPLICATIONS

This application claims the benefit of U.S. Provisional Patent Application No. 62/611,951, filed on Dec. 29, 2017. The disclosure of the above-referenced application is hereby incorporated by reference in its entirety.

### BACKGROUND

Electronic devices (e.g., computing devices, network devices, etc.) may use various cards that include circuit boards and connectors. The connectors may be used to connect the cards to each other. For example, a network switch may have one or more fabric cards (e.g., a component of the network switch) that are coupled to one or more line cards (e.g., another component of the network switch) via one or more connectors. Each line card may have multiple lines, front end connectors, network interfaces, etc. The fabric cards may each contain multiple switch circuits for connecting the line cards.

### SUMMARY

In some implementations, an apparatus is provided. The apparatus includes a circuit board and the circuit board includes a set of processing devices. A first connector is coupled to the circuit board and the set of processing devices. A first housing of the first connector is configured to interface with a second housing of a second connector while the first connector and second connector are inserted into a third connector.

In some implementations, a connector is provided. The connector includes a plurality of connections configured to communicatively couple with a set of processing devices. The connector also includes a housing configured to house the plurality of connections. The housing is configured to interface with a second housing of a second connector while the connector and second connector are inserted into a third connector.

In some implementations, a method is provided. The method includes positioning a first circuit board parallel to a second circuit board. The first circuit board is coupled to a first connector. The second circuit board is coupled to a second connector. The first connector interfaces with the second connector while the first circuit board is positioned parallel to the second circuit board. The method also includes inserting the first connector and the second connector into a third connector, wherein the first connector and the second connector fit within the third connector

Other aspects and advantages of the embodiments will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIGS. 1A and 1B are block diagrams of a network device, in accordance with some embodiments of the present disclosure.

FIG. 2A is a perspective view of connectors, in accordance with some embodiments of the present disclosure.

FIG. 2B is a side view of connectors, in accordance with some embodiments of the present disclosure.

FIGS. 3A-3C are perspective front views of example line cards, in accordance with some embodiments of the present disclosure.

FIGS. 3D-3F are perspective back views of example line cards, in accordance with some embodiments of the present disclosure.

FIGS. 3G and 3H are side front views of example line cards, in accordance with some embodiments of the present disclosure.

FIGS. 3I and 3J are side back views of example line cards, in accordance with some embodiments of the present disclosure.

FIG. 4 is a perspective view of devices which include connectors, in accordance with some embodiments of the present disclosure.

FIG. 5 is a side back view of example line cards, in accordance with some embodiments of the present disclosure.

FIG. 6 is a flow diagram of a method of assembling or servicing a network switch device, which can be practiced with embodiments described herein.

### DETAILED DESCRIPTION

As discussed above, electronic devices (e.g., computing devices, network devices, etc.) may use various cards that include circuit boards and connectors. The connectors may be used to connect the cards to each other. One type of electronic device that uses cards and connectors may be a network device, such as a switch, a router, a bridge, etc. A network device may include multiple cards (e.g., fabric cards, line cards, etc.) that are coupled to each other by one or more connectors.

As the capabilities of electronic devices and user demands on the electronic device increase, the number of cards and/or the number of components on the cards may increase. Connector pin density, routing layer density, and area on the cards (e.g., printed circuit boards) for connectors may be limiting factors in packaging density for these electronic devices. For example, routing layers (e.g., pins, wires, traces, lines, etc.) may be used in the circuit boards to allow the components of the cards to communicate with each other. For example, routing layers may interconnect a set of processing devices on a first card with a set of processing devices on a second card. In another example, routing layers may interconnect memory on a first card with a set of processing devices on a second card. As the number of components (e.g., processing devices, memory, cache, etc.) increase, the number of routing layers may increase as well (in order to connect or interconnect the components). The number of components on a card may increase to a point where the circuit board of the card may not be able to accommodate all of the routing layers that may be used by the components. In addition, it may be expensive to manufacture a circuit board that has enough routing layers to accommodate all of the components on a card.

Obstructions for cooling airflow are also factors for design consideration. For example, having more components on a card may obstruct airflow around the card. In addition, increasing the number of components (e.g., processing device) on a card may cause problems in cooling the components. For example, the components may be close together on the circuit board because there is not enough space to spread the components further apart.

Various implementations, embodiments, and examples described herein have multiple parallel cards mounted orthogonal to and electrically coupled to another card, and solve multiple problems in packaging, connectivity, and cooling of the cards. The parallel cards may include smaller connectors that mate or interface with each other. The smaller connectors may fit within a connector of the other card.

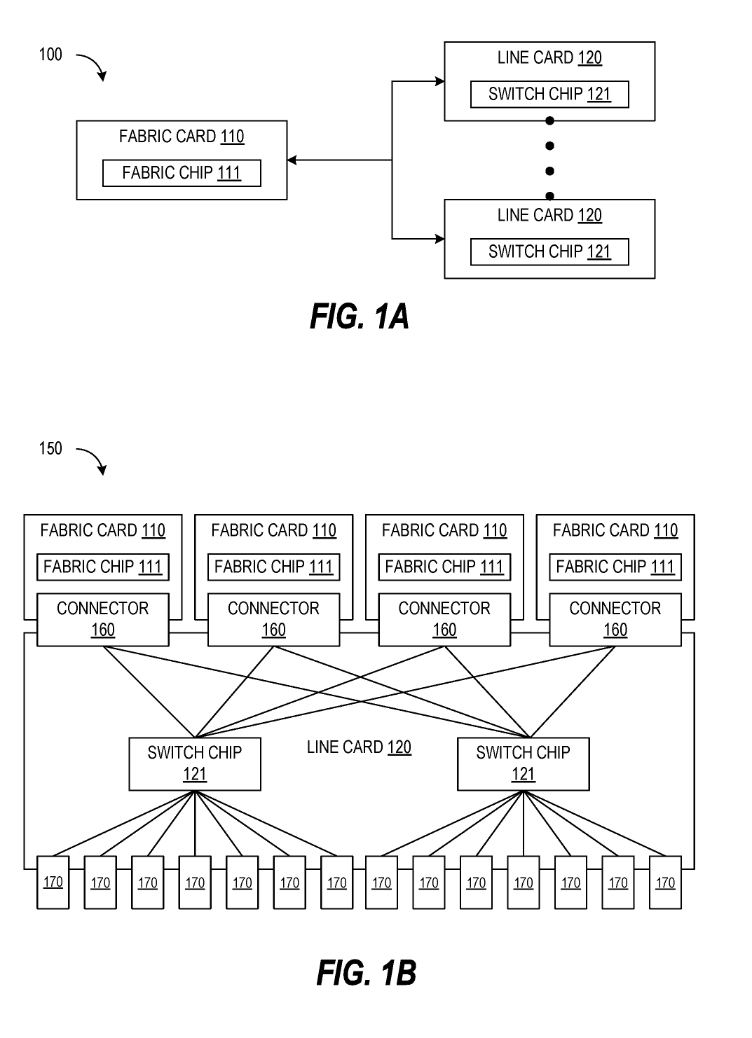

FIG. 1A is a block diagram of a network device 100, in accordance with some embodiments of the present disclosure. Examples of a network device may include a switch (e.g., a network switch), a router (e.g., a network router), a bridge (e.g., a network bridge), etc. The network device 100 includes a fabric card 110 and multiple line cards 120. The fabric card 110 includes a fabric processor 111. The fabric card 110 may communicatively be coupled to multiple line cards 120 via one or more connectors, as discussed in more detail below. Each of the line cards 120 includes a switch processor 121. The switches within the fabric processor 111 may be referred to as switching paths or routing paths. These switching paths or routing paths couple and/or connect ingress and egress ports of fabric processor 111 through the switch fabric in some embodiments. Although the fabric card 110 is illustrated with a fabric processor 111, the fabric card 110 may include a set of fabric processors 111 (e.g., multiple fabric processors 111, one or more fabric processors 111) in other embodiments. In addition, although the line card 120 is illustrated with a switch processor 121, the line card 120 may include a set of switch processors 121 (e.g., multiple switch processors 121, one or more switch processors 121) in other embodiments. The fabric processor 111 may be referred to as a fabric processor and the switching chip 121 may be referred to as switching processors. The fabric processor 111 and switch processor 121 the may also be referred to as processing devices. A processing device may be a device that is capable of executing instructions to perform various operations, functions, tasks, etc. Examples of processing devices may include , a processor, a multi-core processor, a central processing unit (CPU), an application specific integrated circuit (ASIC), a field programmable gate array (FPGA), etc.,

FIG. 1B is a block diagram of a network device 150 (e.g., a switch, a router, etc.), in accordance with some embodiments of the present disclosure. The network device 100 includes fabric cards 110 and a line card 120. Each fabric card 110 includes a fabric processor 111. Each fabric card 110 may be communicatively coupled to the line card 120 via a respective connector 160, as discussed in more detail below. The switches within the fabric processor 111 may be referred to as switching paths or routing paths. These switching paths or routing paths couple and/or connect ingress and egress ports of fabric processor 111 through the switch fabric in some embodiments. The line card 120 includes two switch processors 121. The line card 120 also includes multiple front end connectors 170. The front end connectors 170 may be located on a front panel of the line card 120 such that the front end connectors 170 may be accessible when the line card 120 is inserted or installed into the network device 150 (e.g., into a chassis of the network device 150). The front end connectors 170 may be network interfaces or ports that may accept other devices. For example, the front end connectors 170 may accept small form-factor pluggable (SFP) modules, octal SFP (OSFP) modules, quad SFP (QSFP) modules, etc. In another example, the front end connectors 170 may be network interfaces such as Ethernet ports, optical fiber connectors, etc.

Although the fabric card 110 is illustrated with a fabric processor 111, the fabric card 110 may include a set of fabric processors 111 (e.g., one or more fabric processors 111) in other embodiments. In addition, although the line card 120 is illustrated with two switch processors 121, the line card 120 may include more switch processors 121 in other embodiments. The fabric processor 111 and switch processor 121 the may be referred to as processing devices, as discussed above. As illustrated in FIG. 1B, each switch processor 121 is communicatively coupled to a fabric card 110 via a respective connector 160. For example, the left switch processor 121 is coupled to the four fabric cards 110 via their respective connectors 160, and the right switch processor 121 is coupled to the four fabric cards 110 via their respective connectors 160. This allows each switch processor 121 to communicate data (e.g., transmit and/or receive packets, frames, messages, etc.) with each of the fabric processors 111. Connectors 160 can each include multiple connectors. For example, a connector 160 may include a first connector (e.g., a male connector) on a fabric card 110 and a second connector (e.g., a corresponding female connector) on the line card 120.

As discussed above, the line card 120 includes a circuit board and the switch processors 121 may be coupled to the circuit board. The circuit board may include fourteen routing layers (e.g., pins, lines, traces, wires, etc.) that couple the switch processors 121 to the front end connectors 170. The circuit board may also include eight routing layers that couple the switch processors 121 to each of the fabric processors 111. Increasing the number of switch processors 121 and/or increase the number of front end connectors 170 may increase the number of routing layers. For example, if there are four switch processors 121 and twenty-eight front end connectors 170, a total of forty-four routing layers will be used to connect the switch processors 121 to the front end connectors 170 and the fabric processors. For example, twenty eight routing layers will be used to connect the four switch processors 121 to the front end connectors 170 and sixteen routing layers will be used to connector the four switch processors 121 to the four fabric processors 111. The more routing layers that are used in the line card, the thicker the circuit board should be in order to accommodate the routing layers. Increasing the number of routing layers will increase the thickness, cost and/or weight of the circuit board. Increasing the number of routing layers also increases the complexity of the layout of the routing layers. To accommodate the increase in routing layers, small vias (e.g., connections, pins, traces, wires, lines, etc., that go through the circuit board) may not be usable in order to maintain a proper ratio between the board thickness and the diameter of the vias. Using larger vias may decrease the number of routing layers that may be used in the circuit board. In addition, if too many routing layers are need, it may not be possible to include all of the routing layers within a circuit board.

One issue to address in the illustrated design is how to increase the number of components on a card (e.g., increase the number of processing devices on a line card) while addressing the complexity or number of routing layers for the card. Another issue to address in the illustrated design is how to couple the fabric processors 111 and the line card 120 in a compact manner that does not obstruct airflow inside a chassis or housing of the network device 150. For example, if all of the line cards are arranged parallel to the fabric card and along one edge of the fabric card 110, e.g., with edge connectors, the fabric card becomes unduly large as a result of the linear dimensions required for all of the interconnections. Other arrangements have related packaging issues because of the interconnections with the line cards.

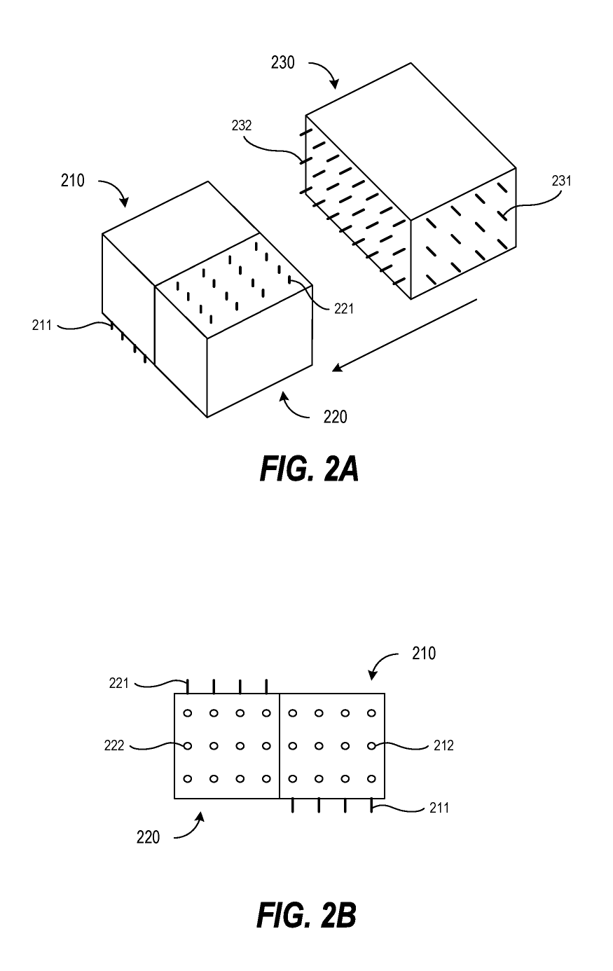

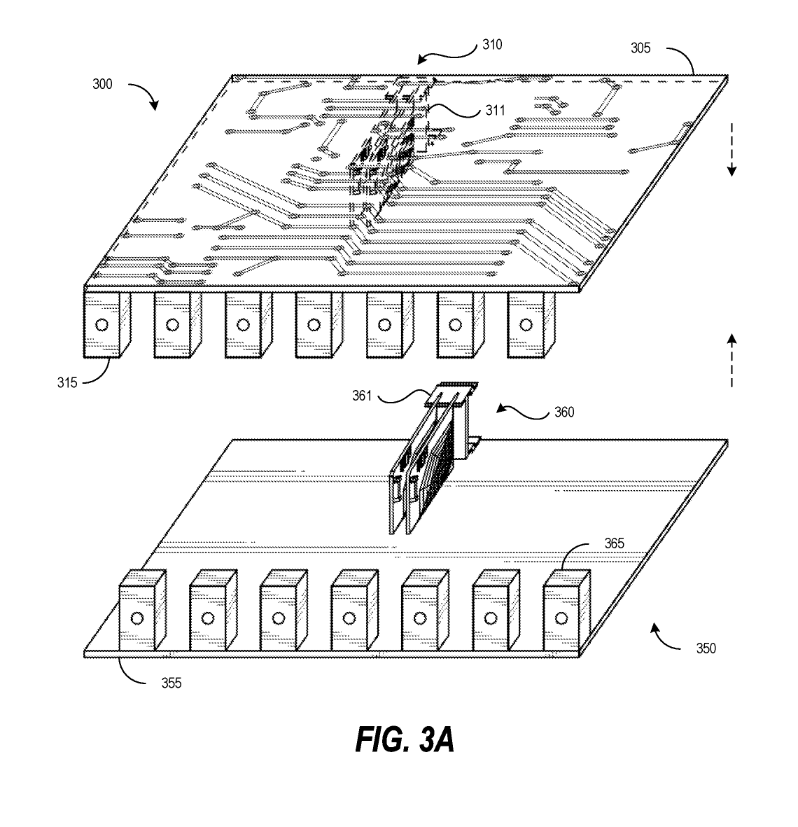

FIG. 2A is a perspective view of connectors 210, 220, and 230, in accordance with some embodiments of the present disclosure. Various orthogonal connectors are available from vendors, with various numbers of conductors, pins, pin layouts, sockets, pin receptacles, socket layouts, dimensions and relative orientations, and embodiments are not limited to the specific connectors shown herein. The conductors, pins, sockets, pin receptacles, etc., may also be referred to as connections. For example, a pin may be referred to as a connection. In another example, a socket or pin receptacle may be referred to as a connection.

As illustrated in FIG. 2A, pins 232 (e.g., wires, lines, traces, etc.) of connector 230 (e.g., a male connector) may be inserted into sockets or pin receptacles of connectors 210 and 220 (e.g., female connectors). Connector 230 also includes solder pins 231 (e.g., wires, lines traces, etc.) which are perpendicular or orthogonal to pins 232. The solder pins 231 may be used to couple, connect, attach, etc., the connector 230 to a first circuit board (e.g., a printed circuit board (PCB)). Connector 210 includes solder pins 211 which are perpendicular in a downward direction to the pins 232 of the connector 230. The solder pins 211 may be used to couple, connect, attach, etc., the connector 210 to a second circuit board, as discussed in more detail below. Connector 220 includes solder pins 221 which are perpendicular in an upward direction to the pins 232 of the connector 230. The solder pins 221 may be used to couple, connect, attach, etc., the connector 220 to a third circuit board, as discussed in more detail below. Although the present disclosure may refer to solder pins, other types of pins or traces may be used. For example, solder tails, press-fit pins, etc., may be used in other embodiments.

The connectors 210 and 220 may interface with each other when the connectors 210 and 220 mate with the connector 230. For example, a wall of the connector 210 may interface (e.g., come into contact with, align with, etc.) a wall of the connector 220. In another example, the two connectors 210 and 220 may be pushed, fitted, or interlocked together. In some embodiments, the connectors 210 and 220 may be orthogonal to the connector 230. For example, the first circuit board (coupled to connector 230) may be orthogonal or perpendicular to the first circuit board (coupled to connector 210), as discussed in more detail below. The first circuit board (coupled to connector 230) may also be orthogonal or perpendicular to the second circuit board (coupled to connector 220), as discussed in more detail below. Thus, the connectors 210 and 220, and the connector 230 may be referred to as orthogonal connectors.

Orthogonal connectors may have a specific handedness or orientation of orthogonality (e.g., as keyed), or may have one connector rotatable with respect to the other connector. It should be appreciated that the mating or engagement of connectors 210 and 220, and connector 230 may utilize any suitable orientation that results in the orthogonal orientation discussed herein. In one embodiment, the first circuit board and the second circuit board would meet each other edge to edge, with the edge of the first circuit board adjacent and perpendicular to the edge of the second circuit board, rather than edge to face as is the case with other board connectors, e.g., that position one circuit board perpendicular and coupled to a central region of a face of another circuit board. The first circuit board and the third circuit board would also meet each other edge to edge, with the edge of the first circuit board adjacent and perpendicular to the edge of the second circuit board.

In one embodiment, the second circuit board may be orthogonal to the first circuit board at a 90 degree angle when the connector 210 is mated or coupled to the connector 230. The third circuit board may be orthogonal to the first circuit board at a 270 degree angle when the connector 220 is mated or coupled to the connector 230. In some embodiments, the connector 230 may be part of a mid-plane or a fabric card, as discussed in more detail below. In other embodiments, the connectors 210, 220, and 230 may include housings, as discussed in more detail below.

The term “connector” is understood to apply to a large variety of connectors with a large variety of numbers of conductors, and to groups of connectors, individual connectors, and components of a connector. For example, a male plug having one or more pins or prongs is considered a connector, a female socket having one or more pin or prong receptacles or socket contacts is considered a connector, and the combination of a male plug and female socket is a connector, as are hermaphrodite connectors and their components. Groups of multiple male connectors are considered a connector, as are groups of female connectors, and groups of hermaphrodite connectors. Connections to a connector can be made for example by crimping, soldering (pins or surface mount), or fastening, and can be made by wires, printed circuit board pads, plated through holes, edges or traces, or other connectors among various possibilities.

FIG. 2B is a side view of connectors 210 and 220, in accordance with some embodiments of the present disclosure. As illustrated in FIG. 2B, connector 210 includes pin receptacles 212 (e.g., sockets) and connector 220 includes pin receptacles 222. As discussed above, pins of another connector may be inserted into the pin receptacles of connectors 212 and 222. Connector 210 includes solder pins 211 and connector 220 includes solder pins 221. The solder pins 211 may be used to couple the connector 210 to a first circuit board and the solder pins 221 may be used to couple the connector 220 to a second circuit board. The first circuit board may be parallel to the second circuit board. Although the present disclosure may refer to solder pins, other types of pins or traces may be used. For example, solder tails, press-fit pins, etc., may be used in other embodiments.

As illustrated in FIG. 2B, the connectors 210 and 220 may interface with each other when the connectors 210 and 220 mate with the connector 230. For example, a right wall of the connector 210 may interface (e.g., come into contact with, align with, etc.) a left wall of the connector 220. In another example, the two connectors 210 and 220 may be pushed, fitted, or interlocked together. The connectors 210 and 220 may include physical features or elements such as rails, slits, slots, grooves, tabs, holes, notches, prongs, etc., that may be used to align the connectors 210 and 220.

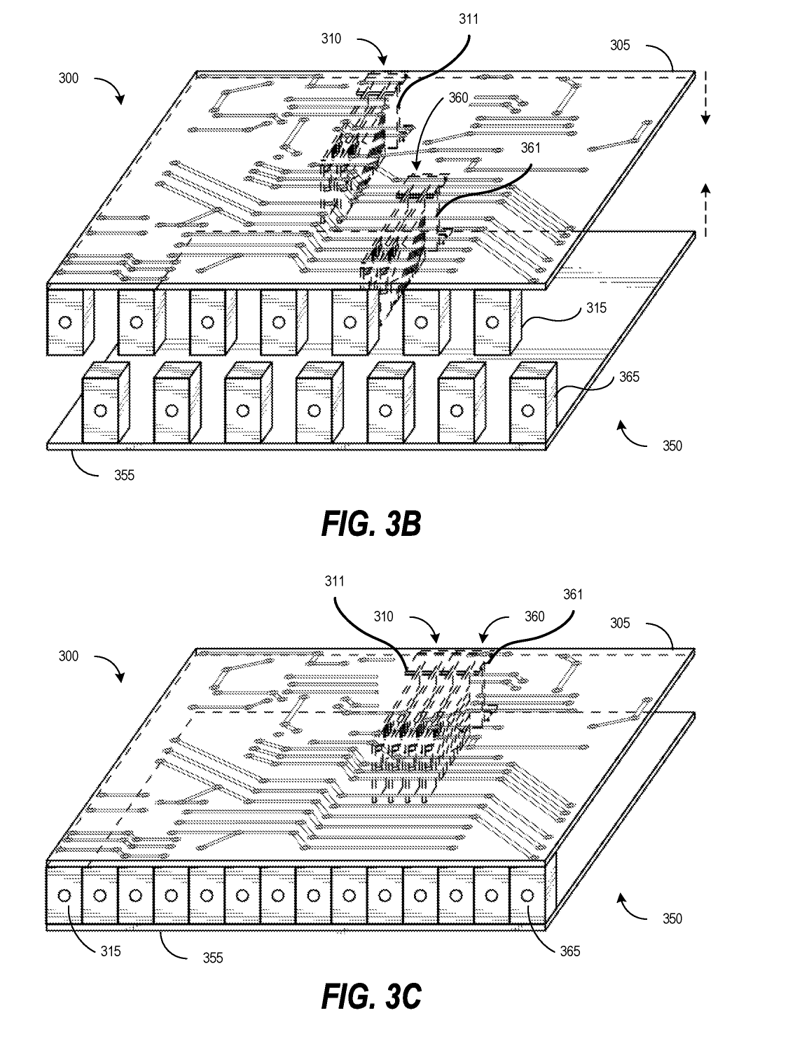

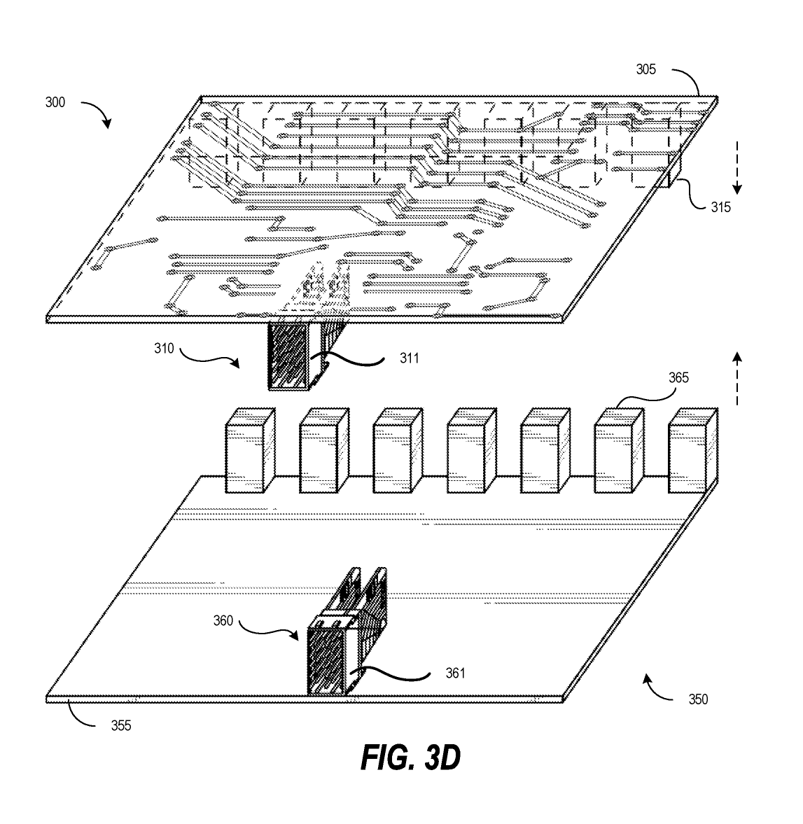

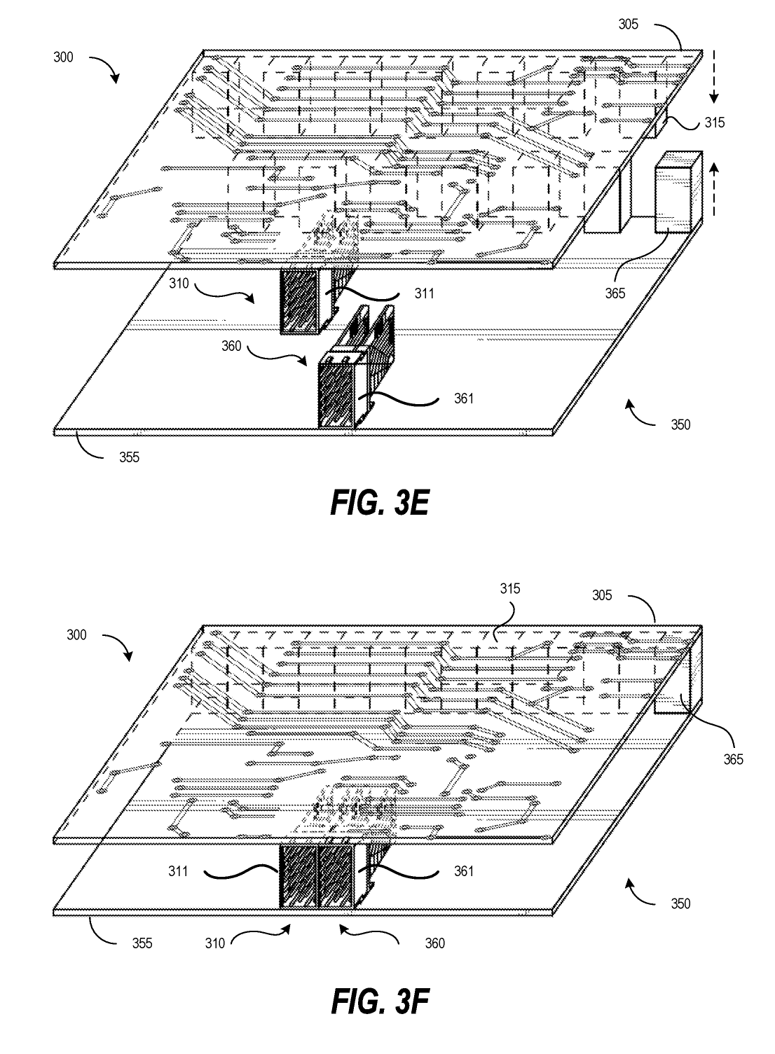

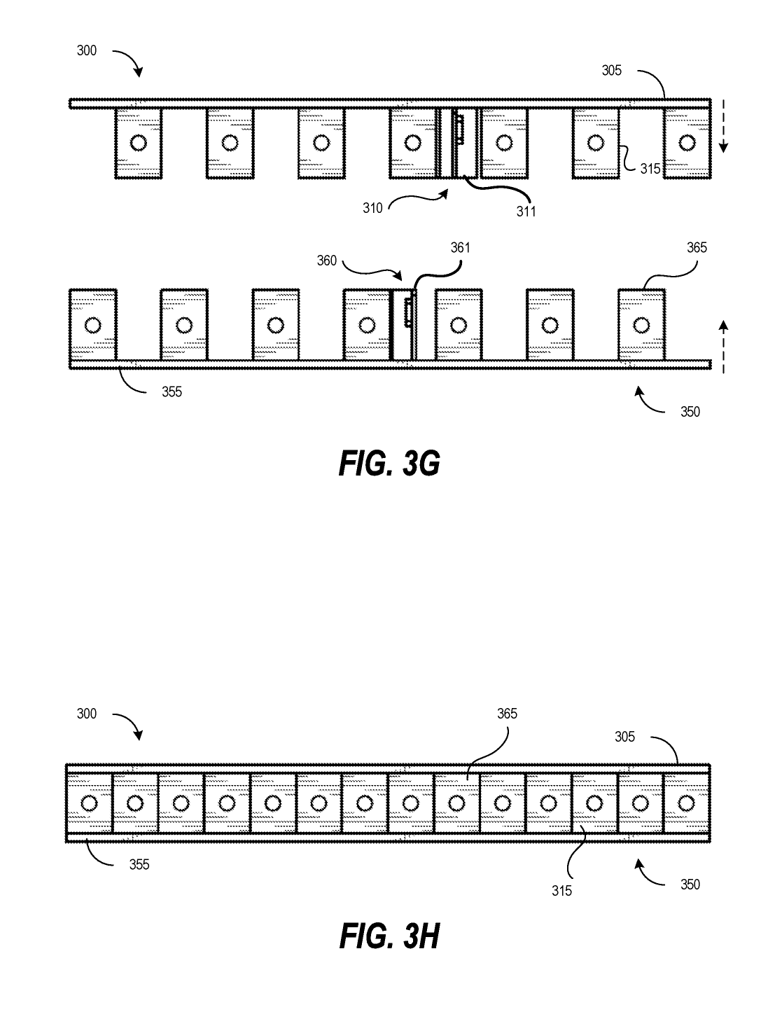

FIG. 3A is a perspective front view of example line cards 300 and 350, in accordance with some embodiments of the present disclosure. The line card 300 includes a circuit board 305, a connector 310, and front end connectors 315 (e.g., seven front end connectors 315). The connector 310 includes pins (not visible in FIG. 3A) and a housing 311. The connector 310 may be coupled to a set of processing devices (e.g., one or more switch processors) which are installed, mounted, located, etc., on the circuit board 305. The front end connectors 315 of the line card 300 may also be communicatively coupled to the set of processing devices on the line card 300. The line card 350 includes a circuit board 355, a connector 360, and front end connectors 365. The connector 360 includes pins (not visible in FIG. 3A) and a housing 361. The connector 360 may be coupled to a set of processing devices which are installed, mounted, located, etc., on the circuit board 355. The front end connectors 365 of the line card 350 may also be communicatively coupled to the set of processing devices on the line card 350.

In one embodiment, the line cards 300 and 350 may be coupled to a fabric card via the connectors 310 and 360, as discussed above. The fabric card may include one or more fabric processors (e.g., a set of processing devices), as discussed above. This may allow the switch processors on the line cards 300 and 350 to communicate data with the one or more fabric processors (e.g., another set processing devices) on the fabric card. In another embodiment, the line cards 300 and 350 may be coupled to a mid-plane via the connectors 310 and 360, as discussed above. For example, the line cards 300 and 350 may be coupled to connector on a mid-plane and the connector on the mid-plane may be coupled to a fabric card.

In one embodiment, the switching chips of the line cards 300 and 350 may be communicatively coupled to one or more fabric processors of the fabric card. For example, the switching chips of line card 300 may be communicatively coupled (e.g., may be able to transmit and/or receive data, packets, messages, frames, etc.) to a fabric processor of the fabric card via the connector 310 and a connector of the fabric card.

Although one set of connectors 310 and 360 are illustrated in FIG. 3A, multiple sets of connectors 310 and 360 may be included in the line cards 300 and 310 in other embodiments. For example, the line card 300 may include multiple connectors 310 which may interface or mate with multiple connectors 360 of line cards 350. This may allow the line cards 300 and 360 to be coupled to multiple fabric cards or to be coupled to multiple connectors on a mid-plane.

In one embodiment, the connector 310 may interface or mate with the connector 360 while the connectors 310 and 360 are inserted into a third connector (e.g., a third connector of a mid-plane or fabric card). For example, a right wall of the connector 310 may come into contact with (e.g., touch) the left wall of the connector 360.

In one embodiment, the connector 310 and the connector 360 may fit within the housing of the third connector. For example, the housing 311 (of the connector 31) and the housing 361 (of the connector 360) while the connectors 310 and 360 are inserted into the third connector.

In one embodiment, the connector 310 and the connector 360 may be male connectors (e.g., connectors with pins) and the third connector may be a female connector (e.g., a connector with holes, sockets, or pin receptacles, etc., to receive the pins of the connectors 310 and 360). In another embodiment (illustrated in FIGS. 2A and 2B), third connector may be a male connector and the connectors 310 and 360 may be female connectors.

In one embodiment, the line cards 300 and 350 may be parallel to each other while the connectors 310 and 360 are inserted into a third connector (of a mid-plane or fabric card). The line cards 300 and 350 may also be parallel to each other as the line cards 300 and 350 are placed together (e.g., are pushed or moved towards each other) as indicated by the dashed arrows. The components on the upper surfaces of the circuit boards 305 and 355 may face each other when the line cards 300 and 350 are placed together.

In another embodiment, the line cards 300 and 350 may be orthogonal to a fabric card or a mid-plane while the connectors 310 and 360 are inserted into a third connector of the fabric card or mid-plan, as discussed in more detail below. For example, line card 300 may be rotated 270 degrees clockwise from the orientation of the fabric card (or mid-plane). In another example, the line cards 350 may be rotated 90 degrees clockwise from the orientation of the fabric card (or mid-plane).

In one embodiment, the connectors 310 and 360 may each occupy half of the housing of the third connector while the connectors 310 and 360 are inserted into the third connector, as discussed in more detail below. For example, the connector 310 may occupy a left half of the housing of the third connector and the connector 360 may occupy a right half of the housing of the third connector (e.g., the connector 310 may be positioned to the left side of connector 360). In another example, the connector 310 may occupy a right half of the housing of the third connector and the connector 360 may occupy a left half of the housing of the third connector (e.g., the connector 310 may be positioned to the right side of connector 360). In a further example, the connector 310 may be located above the connector 360 (e.g., may be on top of the connector 360).

In one embodiment, the front end connectors 315 (of line card 300) and the front end connectors 365 (of line card 350) may interface with each other. For example, as the line card 310 is moved towards the line cards 350, the front end connectors 315 and the front end connectors 365 may align with each other such that the front end connectors 315 and the front end connectors 365 are located adjacent to each other (e.g., to the sides of each other). For example, the leftmost front end connector 365 (of the line card 350) may fit between the two leftmost connectors 315 (of the line card 300).

In some embodiments, the housing 311 and /or the housing 361 may include physical features or elements such as rails, slits, slots, grooves, tabs, holes, notches, prongs, etc., that may be used to align the housing 311 with the housing 361, or vice versa. In other embodiments, the front end connectors 316 and 365 may also include physical features or elements such as rails, slits, slots, grooves, tabs, holes, notches, prongs, etc., that may be used to align the front end connectors 316 and 365. The physical features or elements may be referred to as alignment features or alignment elements.

In one embodiment, line cards 300 and 350 may be equivalent to the line card 120 illustrated in FIG. 1B. For example, the line card 120 may be divided in half to form the line cards 300 and 350. Because the line cards 300 and 350 have one switch chip each (instead of having two switch chips), the number of routing layers within the circuit boards 305 and 355 may be reduced. This may be referred to as reducing the density of the routing layers for the circuit boards 305 and 355. Reducing the routing layers within the circuit boards 305 and 355 may reduce the cost to manufacture the line cards 300 and 350. This may also allow the circuit line cards 300 and 350 to support more network interfaces than the line card 120 because additional routing may be added due to the reduced density of the routing layers in the line cards 300 and 350, when compared to the line card 120. In addition, cooling of the line cards 300 and 350 may be improved when compared to the line card 120. For example the sets of switch processors may be distributed among the line cards 300 and 350 may allow for better airflow and may spread out the generation of heat (by the switch processors) because the sets of switch processors are not located on the same line card.

FIG. 3B is a perspective front view of example line cards, in accordance with some embodiments of the present disclosure. The line card 300 includes a circuit board 305, a connector 310, and front end connectors 315. The connector 310 includes pins and a housing 311. The line card 350 includes a circuit board 355, a connector 360, and front end connectors 365. The connector 360 includes pins and a housing 361. As discussed above, the line cards 300 and 350 may be coupled to fabric card or a mid-plane via the connectors 310 and 360. As illustrated in FIG. 3B, the line cards 300 and 350 are moved towards each other. The line cards 300 and 350 are positioned parallel to each other as they are moved closer towards each other (e.g., moved close together, moved towards each other, pushed towards each other, etc.), when compared with FIG. 3A.

FIG. 3C is a perspective front view of example line cards, in accordance with some embodiments of the present disclosure. The line card 300 includes a circuit board 305, a connector 310, and front end connectors 315. The connector 310 includes pins and a housing 311. The line card 350 includes a circuit board 355, a connector 360, and front end connectors 365. The connector 360 includes pins and a housing 361. As discussed above, the line cards 300 and 350 may be coupled to fabric card or a mid-plane via the connectors 310 and 360. As illustrated in FIG. 3C, the line cards 300 and 350 are fitted or mated together. For example, the portions of the line cards 300 and 350 may interface (e.g., come into contact) with each other.

In one embodiment, the connector 310 may interface or mate with the connector 360 while the connectors 310 and 360 are inserted into a third connector, as discussed above. In another embodiment, the connector 310 and the connector 360 may fit within the housing of the third connector. In one embodiment, the connector 310 and the connector 360 may be male connectors and the third connector may be a female connector, or vice versa.

FIG. 3D is a perspective back view of example line cards 300 and 350, in accordance with some embodiments of the present disclosure. The line card 300 includes a circuit board 305, a connector 310, and front end connectors 315, as discussed above. The connector 310 includes pins and a housing 311, as discussed above. The line card 350 includes a circuit board 355, a connector 360, and front end connectors 365, as discussed above. The connector 360 includes pins and a housing 361, as discussed above. The line cards 300 and 350 may be coupled to fabric card or a mid-plane via the connectors 310 and 360, as discussed above. As illustrated in FIG. 3D, the line cards 300 and 350 are moved towards each other (as indicated by the dashed lines).

FIG. 3E is a perspective back view of example line cards, in accordance with some embodiments of the present disclosure. The line card 300 includes a circuit board 305, a connector 310, and front end connectors 315. The connector 310 includes pins and a housing 311. The line card 350 includes a circuit board 355, a connector 360, and front end connectors 365. The connector 360 includes pins and a housing 361. As discussed above, the line cards 300 and 350 may be coupled to fabric card or a mid-plane via the connectors 310 and 360. As illustrated in FIG. 3E, the line cards 300 and 350 are moved towards each other. The line cards 300 and 350 are positioned parallel to each other as they are moved closer towards each other (e.g., moved close together, moved towards each other, pushed towards each other, etc.), when compared with FIG. 3A.

FIG. 3F is a perspective back view of example line cards, in accordance with some embodiments of the present disclosure. The line card 300 includes a circuit board 305, a connector 310, and front end connectors 315. The connector 310 includes pins and a housing 311. The line card 350 includes a circuit board 355, a connector 360, and front end connectors 365. The connector 360 includes pins and a housing 361. As discussed above, the line cards 300 and 350 may be coupled to fabric card or a mid-plane via the connectors 310 and 360. As illustrated in FIG. 3F, the line cards 300 and 350 are fitted or mated together. For example, the portions of the line cards 300 and 350 may interface (e.g., come into contact) with each other.

In one embodiment, the connector 310 may interface or mate with the connector 360 while the connectors 310 and 360 are inserted into a third connector, as discussed above. In another embodiment, the connector 310 and the connector 360 may fit within the housing of the third connector. In one embodiment, the connector 310 and the connector 360 may be male connectors and the third connector may be a female connector, or vice versa.

FIG. 3G is a front view of example line cards, in accordance with some embodiment of the present disclosure. The line card 300 includes a circuit board 305, a connector 310, and front end connectors 315. The connector 310 includes pins and a housing 311. The line card 350 includes a circuit board 355, a connector 360, and front end connectors 365. The connector 360 includes pins and a housing 361. As discussed above, the line cards 300 and 350 may be coupled to fabric card or a mid-plane via the connectors 310 and 360. As illustrated in FIG. 3G, the line cards 300 and 350 are moved towards each other. The line cards 300 and 350 are positioned parallel to each other as they are moved closer towards each other (e.g., moved close together, moved towards each other, pushed towards each other, etc.

FIG. 3H is a front view of example line cards, in accordance with some embodiment of the present disclosure. The line card 300 includes a circuit board 305, a connector 310, and front end connectors 315. The connector 310 includes pins and a housing 311. The line card 350 includes a circuit board 355, a connector 360, and front end connectors 365. The connector 360 includes pins and a housing 361. As discussed above, the line cards 300 and 350 may be coupled to fabric card or a mid-plane via the connectors 310 and 360. As illustrated in FIG. 3H, the line cards 300 and 350 are fitted or mated together. For example, the portions of the line cards 300 and 350 may interface (e.g., come into contact) with each other.

In one embodiment, the front end connectors 315 may interface or mate with the front end connectors 365 when the line cards 300 and 350 are mated/fitted together, as discussed above. For example, the right wall of the leftmost front end connector 315 may interface (e.g., contact, touch, etc.) the left wall of the leftmost front end connector 365. As discussed above, the front end connectors 315 and 365 may include physical features or elements such as rails, slits, slots, grooves, tabs, holes, notches, prongs, etc., that may be used to align the connectors 310 and 360.

FIG. 3I is a front view of example line cards, in accordance with some embodiment of the present disclosure. The line card 300 includes a circuit board 305, a connector 310, and front end connectors 315. The connector 310 includes pins and a housing 311. The line card 350 includes a circuit board 355, a connector 360, and front end connectors 365. The connector 360 includes pins and a housing 361. As discussed above, the line cards 300 and 350 may be coupled to fabric card or a mid-plane via the connectors 310 and 360. As illustrated in FIG. 3I, the line cards 300 and 350 are moved towards each other. The line cards 300 and 350 are positioned parallel to each other as they are moved closer towards each other (e.g., moved close together, moved towards each other, pushed towards each other, etc.

FIG. 3J is a front view of example line cards, in accordance with some embodiment of the present disclosure. The line card 300 includes a circuit board 305, a connector 310, and front end connectors 315. The connector 310 includes pins and a housing 311. The line card 350 includes a circuit board 355, a connector 360, and front end connectors 365. The connector 360 includes pins and a housing 361. As discussed above, the line cards 300 and 350 may be coupled to fabric card or a mid-plane via the connectors 310 and 360. As illustrated in FIG. 3J, the line cards 300 and 350 are fitted or mated together. For example, the portions of the line cards 300 and 350 may interface (e.g., come into contact) with each other.

In one embodiment, the connector 310 may interface or mate with the connector 360 when the line cards 300 and 350 are mated/fitted together, as discussed above. For example, the left wall of the housing 311 of the connector 310 may contact the right wall of the housing 361 of the connector 361. As discussed above, the connectors 310 and 360 (e.g., the housings 311 and 361 of the connectors 310 and 360) may include physical features or elements such as rails, slits, slots, grooves, tabs, holes, notches, prongs, etc., that may be used to align the connectors 310 and 360.

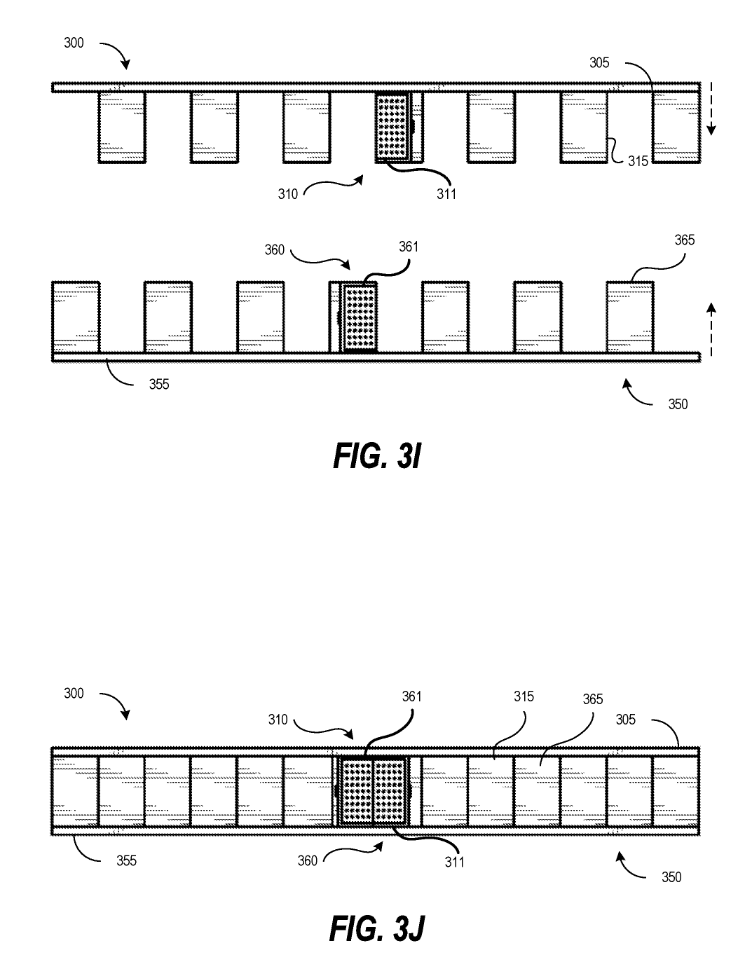

FIG. 4 is a perspective view of devices 400, 450, and 490 which include connectors 405, 455, and 495, in accordance with some embodiments of the present disclosure. The devices 400, 450, and 490 may be any type of device that includes a circuit board and connectors which may be used to couple the devices 400, 450, and 490 together. For example, the devices 400, 450, and 490 may be sound cards, video cards, motherboards, etc. In another example, devices 400 and 450 may be line cards, and device 490 may be a fabric card or a mid-plan. The device 400 includes a circuit board 405 and a connector 410. The connector 410 includes pin receptacles 412 and a housing 411. The device 450 includes a circuit board 455 and a connector 460, and front end connectors 365. The connector 460 includes pin receptacles 462 and a housing 461. As illustrated in FIG. 4, the connectors 410 and 460 may be female connectors. Connector 495 may be a male connector.

In one embodiment, one or more components of the devices 400 and 450 may be communicatively coupled to one or more components of the device 490. For example, a processing device of the device 400 may be communicatively coupled to a memory of the device 490. In another embodiment, the connector 410 may interface or mate with the connector 460 while the connectors 410 and 460 are inserted into connector 495. For example, a right wall 413 of the connector 410 may come into contact with (e.g., touch) the left wall 463 of the connector 460.

In one embodiment, the connector 410 and the connector 460 may fit within the housing 496 of the third connector 495. For example, device 400 may be fitted or mated with device 450 such that the connector 410 interfaces with the connector 460, as illustrated by the arrow marked “1.” After fitting or mating the device 400 with the device 450, the connectors 410 and 460 may be inserted into the housing 496 of the connector 495, as illustrated by the arrow marked “2.” As illustrated in FIG. 4, the circuit boards 405 and 455 may be parallel to each other. Circuit boards 405 and 455 are also orthogonal (e.g., perpendicular) to the circuit board 497. For example, circuit board 405 may be rotated 270 degrees clockwise from the orientation of circuit board 497 and circuit board 455 may be rotated 90 degrees clockwise from the orientation of circuit board 497.

In one embodiment, the connectors 410 and 460 may each occupy half of the housing 496 of the connector 495 while the connectors 410 and 460 are inserted into the third connector, as discussed in more detail below. For example, the connector 410 may occupy a left half of the housing 496 of the connector 495 and the connector 460 may occupy a right half of the housing 496 of the connector 495. In other embodiments, the housings 411, 461, and/or 496 may include physical features or elements such as rails, slits, slots, grooves, tabs, holes, notches, prongs, etc., that may be used to align the housings 411, 461, and/or 496 with each other.

In some embodiments, the apparatus where the devices 400, 450, and/or 490 may be located/installed may include ejectors (not illustrated in FIG. 4), for removal of device 400, 50, and/or 490. For example, a housing or chassis of the apparatus may include an ejector for removing the connector 410 from the connector 495. Each ejector could be or include a lever, spring mounted or hinged and mounted to the housing or chassis of the apparatus. Various designs and configurations of ejectors may be used in different embodiments. In other embodiments, ejectors may not be used and the devices 400, 450, and/or 490 may be removable upon removal of fasteners or release of one or more detent mechanisms.

In some embodiments, each connector 410, 460, and 495 is a single component, and in other embodiments, connectors 410, 460, and 495 are combined into one connector. Collectively, the combination of connectors 410, 460, and 495 in various embodiments can be viewed as a connector, or multiple connectors.

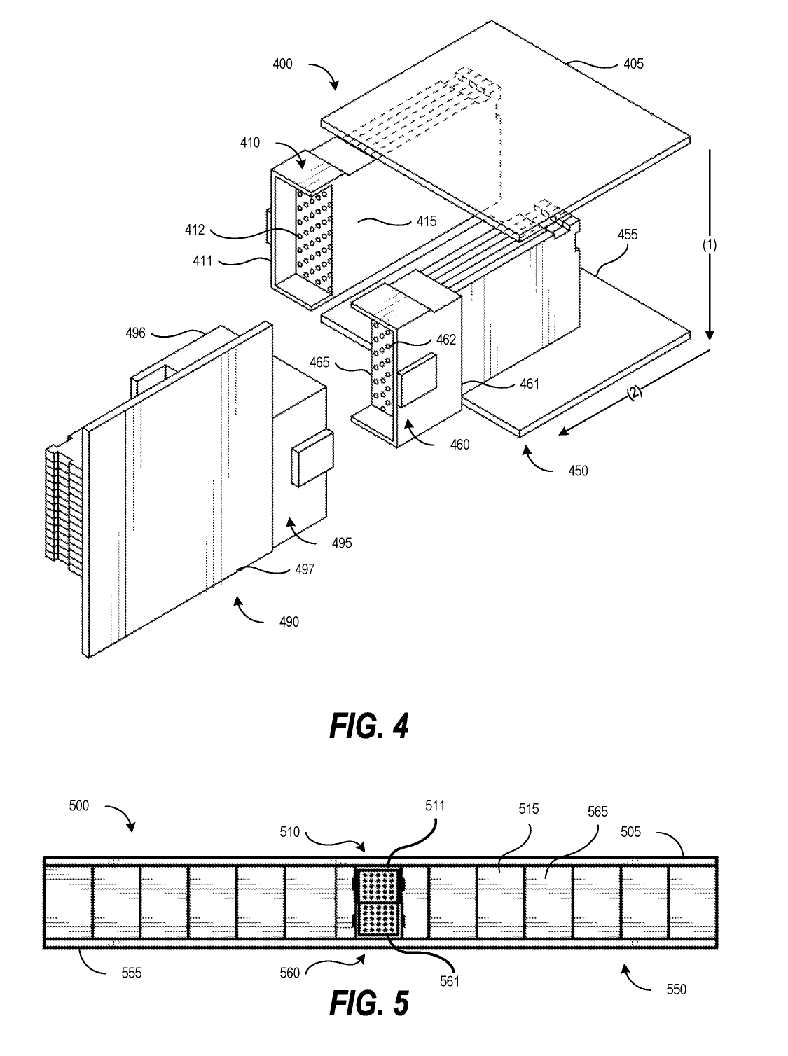

FIG. 5 is a back view of example line cards 500 and 550, in accordance with some embodiment of the present disclosure. The line card 500 includes a circuit board 505, a connector 510, and front end connectors 515. The connector 510 includes pins and a housing 511. The line card 350 includes a circuit board 555, a connector 560, and front end connectors 565. The connector 560 includes pins and a housing 561. As discussed above, the line cards 500 and 550 may be coupled to fabric card or a mid-plane via the connectors 510 and 560. As illustrated in FIG. 5, the line cards 500 and 550 are fitted or mated together. For example, the portions of the line cards 500 and 550 may interface (e.g., come into contact) with each other.

In one embodiment, the connector 510 may interface or mate with the connector 560 when the line cards 500 and 550 are mated/fitted together, as discussed above. The connector 510 may be located above the connector 560 when the line cards 400 and 550 are mated together. For example, the top wall of the housing 511 of the connector 510 may contact the top wall of the housing 561 of the connector 561. As discussed above, the connectors 510 and 560 (e.g., the housings 511 and 561 of the connectors 510 and 560) may include physical features or elements such as rails, slits, slots, grooves, tabs, holes, notches, prongs, etc., that may be used to align the connectors 510 and 560.

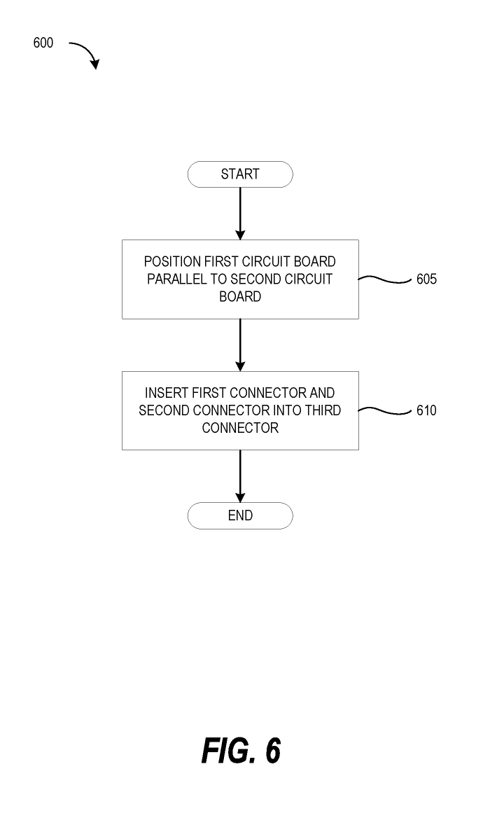

FIG. 6 is a flow diagram of a method 600 of assembling a device, which can be practiced with embodiments described herein. It should be appreciated that the blocks of the method 600 in FIG. 6 can be performed in differing orders, groupings, or subsets than shown in FIG. 6, for various purposes or user preferences. At block 605, a first circuit board is positioned parallel to a second circuit board. A first connector of the first circuit board may interface with a second connector of the second circuit board. For example, referring to FIG. 4, a right wall of the first connector may interface with a left wall of the second connector. The first and second connector may include alignment features or components (e.g., rails, slits, slots, grooves, tabs, holes, notches, prongs, etc.) that may be used to properly fit, interface, mate, etc., the first connector with the second connector. At block 610, the first connector and the second connector may be inserted into a third connector of a third circuit board. For example, referring to FIG. 4, the connectors 410 and 460 may be inserted into the connector 495 after the connectors 410 and 460 have interface (e.g., have mated or fitted together). The blocks 605 and 610 can be used to assemble a device, such as a network device. For example, the blocks 605 and 610 may be used to install one or more line cards, fabrics, etc., into the network device.

Detailed illustrative embodiments are disclosed herein. However, specific functional details disclosed herein are merely representative for purposes of describing embodiments. Embodiments may, however, be embodied in many alternate forms and should not be construed as limited to only the embodiments set forth herein. It should be appreciated that descriptions of direction and orientation are for convenience of interpretation, and the apparatus is not limited as to orientation with respect to gravity. In other words, the apparatus could be mounted upside down, right side up, diagonally, vertically, horizontally, etc., and the descriptions of direction and orientation are relative to portions of the apparatus itself, and not absolute.

It should be understood that although the terms first, second, etc. may be used herein to describe various steps or calculations, these steps or calculations should not be limited by these terms. These terms are only used to distinguish one step or calculation from another. For example, a first calculation could be termed a second calculation, and, similarly, a second step could be termed a first step, without departing from the scope of this disclosure. As used herein, the term “and/or” and the “/” symbol includes any and all combinations of one or more of the associated listed items.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

With the above embodiments in mind, it should be understood that the embodiments might employ various computer-implemented operations involving data stored in computer systems. These operations are those requiring physical manipulation of physical quantities. Usually, though not necessarily, these quantities take the form of electrical or magnetic signals capable of being stored, transferred, combined, compared, and otherwise manipulated. Further, the manipulations performed are often referred to in terms, such as producing, identifying, determining, or comparing. Any of the operations described herein that form part of the embodiments are useful machine operations. The embodiments also relate to a device or an apparatus for performing these operations. The apparatus can be specially constructed for the required purpose, or the apparatus can be a general-purpose computer selectively activated or configured by a computer program stored in the computer. In particular, various general-purpose machines can be used with computer programs written in accordance with the teachings herein, or it may be more convenient to construct a more specialized apparatus to perform the required operations.

A module, an application, a layer, an agent or other method-operable entity could be implemented as hardware, firmware, or a processor executing software, or combinations thereof. It should be appreciated that, where a software-based embodiment is disclosed herein, the software can be embodied in a physical machine such as a controller. For example, a controller could include a first module and a second module. A controller could be configured to perform various actions, e.g., of a method, an application, a layer or an agent.

The embodiments can also be embodied as computer readable code on a tangible non-transitory computer readable medium. The computer readable medium is any data storage device that can store data, which can be thereafter read by a computer system. Examples of the computer readable medium include hard drives, network attached storage (NAS), read-only memory, random-access memory, CD-ROMs, CD-Rs, CD-RWs, magnetic tapes, and other optical and non-optical data storage devices. The computer readable medium can also be distributed over a network coupled computer system so that the computer readable code is stored and executed in a distributed fashion. Embodiments described herein may be practiced with various computer system configurations including hand-held devices, tablets, microprocessor systems, microprocessor-based or programmable consumer electronics, minicomputers, mainframe computers and the like. The embodiments can also be practiced in distributed computing environments where tasks are performed by remote processing devices that are linked through a wire-based or wireless network.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

Various units, circuits, or other components may be described or claimed as “configured to” or “configurable to” perform a task or tasks. In such contexts, the phrase “configured to” or “configurable to” is used to connote structure by indicating that the units/circuits/components include structure (e.g., circuitry) that performs the task or tasks during operation. As such, the unit/circuit/component can be said to be configured to perform the task, or configurable to perform the task, even when the specified unit/circuit/component is not currently operational (e.g., is not on). The units/circuits/components used with the “configured to” or “configurable to” language include hardware—for example, circuits, memory storing program instructions executable to implement the operation, etc. Reciting that a unit/circuit/component is “configured to” perform one or more tasks, or is “configurable to” perform one or more tasks, is expressly intended not to invoke 35 U.S.C. 112, sixth paragraph, for that unit/circuit/component. Additionally, “configured to” or “configurable to” can include generic structure (e.g., generic circuitry) that is manipulated by software and/or firmware (e.g., an FPGA, an ASIC, or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks. “Configurable to” is expressly intended not to apply to blank media, an unprogrammed processor or unprogrammed generic computer, or an unprogrammed programmable logic device, programmable gate array, or other unprogrammed device, unless accompanied by programmed media that confers the ability to the unprogrammed device to be configured to perform the disclosed function(s).

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

What is claimed is:

1. An apparatus, comprising:
a circuit board comprising a set of processing devices;
a first connector coupled to the circuit board and the set of processing devices, wherein a first housing of the first connector is configured to interface with a second housing of a second connector while the first connector and second connector are inserted into a third connector.

2. The apparatus of claim 1, wherein the first connector and the second connector fit within a third housing of the third connector.

3. The apparatus of claim 1, wherein:
the first connector and the second connector comprise male connectors; and
the third connector comprises a female connector.

4. The apparatus of claim 1, wherein:
the first connector and the second connector comprise female connectors; and
the third connector comprises a male connector.

5. The apparatus of claim 1, wherein:
the apparatus comprises a first line card;
a second line card comprises the second connector; and
a fabric card comprises the third connector.

6. The apparatus of claim 5, wherein:
the set of processing devices comprises a first set of switch processors;
the second line card comprises a second set of switch processors; and
the fabric card comprises a set of fabric processors.

7. The apparatus of claim 6, wherein:
the first set of switch processors is communicatively coupled to the set of fabric processors via the first connector and the third connector; and
the second set of switch processors is communicatively coupled to the set of fabric processors via the second connector and the third connector.

8. The apparatus of claim 1, wherein the apparatus is parallel to a second apparatus comprising the second connector.

9. The apparatus of claim 8, wherein the apparatus is orthogonal to a third apparatus comprising the third connector.

10. The apparatus of claim 1, wherein the first connector occupies a first half of the third connector and the second connector is occupies a second half of the third connector while the first connector and second connector are inserted into the third connector.

11. The apparatus of claim 1, wherein the first connector is positioned to a side of the second connector while the first connector and the second connector are inserted into the third connector.

12. The apparatus of claim 1, wherein the first connector is positioned on top of the second connector while the first connector and the second connector are inserted into the third connector.

13. The apparatus of claim 1, wherein the first connector is positioned below of the second connector while the first connector and the second connector are inserted into the third connector.

14. The apparatus of claim 1, further comprising:
a set of network interfaces communicatively coupled to the set of processing devices.

15. The apparatus of claim 1, wherein the set of network interfaces are configured to interface with a second set of network interfaces of a second card.

16. A connector, comprising:
a plurality of connections configured to communicatively couple with a set of processing devices;
a housing configured to house the plurality of connections, wherein the housing is configured to interface with a second housing of a second connector while the connector and second connector are inserted into a third connector.

17. The connector of claim 16, wherein the connector and the second connector fit within at third housing of the third connector.

18. The connector of claim 16, wherein:
the connector and the second connector comprise male connectors; and
the third connector comprises a female connector.

19. The connector of claim 16, wherein:
the connector and the second connector comprise female connectors; and
the third connector comprises a male connector.

20. The connector of claim 1, wherein:
a first line card comprises the connector;
a second line card comprises the second connector; and
a fabric card comprises the third connector.

21. The connector of claim 20, wherein:
the first line card comprises a first set of switch processors;
the second line card comprises a second set of switch processors; and
the fabric card comprises a set of fabric processors.

22. The connector of claim 21, wherein:
the first set of switch processors is communicatively coupled to the set of fabric processors via the connector and the third connector; and
the second set of switch processors is communicatively coupled to the set of fabric processors via the second connector and the third connector.

23. The connector of claim 16, wherein an apparatus comprising the connector is parallel to a second apparatus comprising the second connector.

24. The connector of claim 23, wherein the apparatus is orthogonal to a third apparatus comprising the third connector.

25. The connector of claim 16, wherein the connector occupies a first half of the third connector and the second connector is occupies a second half of the third connector while the connector and second connector are inserted into the third connector.

26. The connector of claim 16, wherein the connector is positioned to a side of the second connector while the connector and the second connector are inserted into the third connector.

27. The connector of claim 16, wherein the connector is positioned on top of the second connector while the connector and the second connector are inserted into the third connector.

28. The connector of claim 16, wherein the connector is positioned below of the second connector while the connector and the second connector are inserted into the third connector.

29. A method of assembling a device, comprising:
positioning a first circuit board parallel to a second circuit board, wherein:
the first circuit board is coupled to a first connector;
the second circuit board is coupled to a second connector; and
the first connector interfaces with the second connector while the first circuit board is positioned parallel to the second circuit board; and
inserting the first connector and the second connector into a third connector, wherein the first connector and the second connector fit within the third connector.
